(19) United States
(12) Patent Application Publication
(10) Pub. No.: US 2026/0130268 A1
(43) Pub. Date: May 7, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Hsing-Yu LIU, Taichung City (TW); Chih-Sheng LIN, Taichung City (TW); Chih-Yuan SHIH, Taichung City (TW)

(21) Appl. No.: 19/004,791

(22) Filed: Dec. 30, 2024

(30) Foreign Application Priority Data
Nov. 5, 2024 (TW) 113142364

(51) Int. Cl. H01L 23/00; H01L 23/31

(52) U.S. Cl. CPC H10W 74/111; H10W 70/09; H10W 70/60

(57) ABSTRACT

An electronic package and a manufacturing method thereof are provided, in which an encapsulating layer embedded with at least one electronic component is provided, then a wiring structure and a circuit structure are sequentially formed on the encapsulating layer, and at least one reinforced blind via is formed in the circuit structure to disperse the stresses in the wiring structure and the circuit structure, thereby preventing the problem of cracking from occurring to the wiring structure or the circuit structure.

### CROSS-REFERENCE TO RELATED APPLICATIONS

The present application is based upon and claims the right of priority to TW Patent Application No. 113142364, filed Nov. 5, 2024, the disclosure of which is hereby incorporated by reference herein in its entirety for all purposes

### BACKGROUND

### 1. Technical Field

The present disclosure relates to a semiconductor packaging technology, and more particularly, to an electronic package that can improve reliability and a manufacturing method thereof.

### 2. Description of Related Art

In order to ensure the continued miniaturization and multi-functionality of electronic products and communication equipment, semiconductor packages need to develop towards miniaturization in order to facilitate the connection of multiple pins. For example, packaging types including flip-chip packaging processes, fan-out wiring and embedded component processes, etc., are commonly used in advanced packaging processes.

FIG. 1A to FIG. 1C are schematic cross-sectional views illustrating a manufacturing method of a conventional semiconductor package 1.

As shown in FIG. 1A, a plurality of semiconductor chips 12 are disposed on a carrier 9, and then the semiconductor chips 12 are encapsulated by an encapsulant 13.

As shown in FIG. 1B, a build-up structure 15 is formed on the encapsulant 13, and a plurality of solder bumps 16 are formed on the build-up structure 15, wherein the build-up structure 15 includes a dielectric layer 150 formed on the encapsulant 13, a circuit layer 151 formed on the dielectric layer 150, and a plurality of conductive blind holes 152 formed in the dielectric layer 150. The conductive blind holes 152 are electrically connected to the circuit layer 151 and the semiconductor chips 12.

As shown in FIG. 1C, the carrier 9 is removed, and a singulation process is performed along a cutting path S shown in FIG. 1B.

However, in the manufacturing method of the conventional semiconductor package 1, the semiconductor chips 12 are first embedded in the encapsulant 13, and then the build-up structure 15 is formed. Therefore, no underfill is used as a stress buffer mechanism between the build-up structure 15 and the semiconductor chips 12, and the build-up structure 15 is prone to stress concentration problems in subsequent processes so that the build-up structure 15 is to be cracked (such as cracks K shown in FIG. 1C), thereby damaging the circuit layer 151.

Therefore, there is a need for a solution that addresses the aforementioned shortcomings in the prior art.

### SUMMARY

In view of the aforementioned shortcomings of the prior art, the present disclosure provides an electronic package, which comprises: an encapsulating layer; at least one electronic component embedded in the encapsulating layer; a wiring structure formed on the encapsulating layer and including an insulating layer formed on the encapsulating layer, a wiring layer formed on the insulating layer, and a plurality of first conductive blind vias formed in the insulating layer, wherein the plurality of first conductive blind vias are electrically connected to the wiring layer and the at least one electronic component; a circuit structure formed on the wiring structure and including at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the first conductive blind vias and the second conductive blind vias are offset from each other, and a target area is formed in the dielectric layer between the first conductive blind vias and the second conductive blind vias; and a reinforced blind via formed in the target area of the dielectric layer.

The present disclosure also provides a method of manufacturing an electronic package, the method comprises: forming an encapsulating layer on at least one electronic component to encapsulate the at least one electronic component; forming a wiring structure on the encapsulating layer, wherein the wiring structure includes an insulating layer formed on the encapsulating layer, a wiring layer formed on the insulating layer, and a plurality of first conductive blind vias formed in the insulating layer, wherein the plurality of first conductive blind vias are electrically connected to the wiring layer and the at least one electronic component; forming a circuit structure on the wiring structure, wherein the circuit structure includes at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the first conductive blind vias and the second conductive blind vias are offset from each other, and a target area is formed in the dielectric layer between the first conductive blind vias and the second conductive blind vias; and forming a reinforced blind via in the target area of the dielectric layer.

In the aforementioned electronic package and method, the wiring structure and the circuit structure are of redistribution layer specifications.

In the aforementioned electronic package and method, the circuit structure includes a plurality of the dielectric layers. For example, a plurality of the reinforced blind vias are arranged in the different dielectric layers.

In the aforementioned electronic package and method, a plurality of the reinforced blind vias are arranged in the single dielectric layer.

In the aforementioned electronic package and method, the reinforced blind via is located in a vertical projection area of the electronic component.

In the aforementioned electronic package and method, the reinforced blind via is located in the dielectric layer adjacent to the insulating layer.

In the aforementioned electronic package and method, the reinforced blind via, the first conductive blind vias and the second conductive blind vias are offset from each other.

In the aforementioned electronic package and method, a planar shape of the reinforced blind via is a geometric figure.

In the aforementioned electronic package and method, a width of the reinforced blind via is less than or equal to a width of the circuit layer.

As can be understood from the above, in the electronic package and manufacturing method thereof according to the present disclosure, at least one reinforced blind via is formed in the target area to disperse the stresses in the wiring structure and the circuit structure. Therefore, compared with the prior art, the electronic package can prevent the problem of stress concentration from occurring to the wiring structure and the circuit structure and prevent the problem of cracking from occurring to the wiring structure or the circuit structure, thereby preventing the wiring layer or the circuit layer from being damaged to improve the yield and reliability of the product.

### BRIEF DESCRIPTION OF THE DRAWINGS

FIG. 1A to FIG. 1C are schematic cross-sectional views illustrating a manufacturing method of a conventional semiconductor package.

FIG. 2A to FIG. 2D are schematic cross-sectional views illustrating a manufacturing method of an electronic package of the present disclosure.

FIG. 2E is a schematic cross-sectional view illustrating a subsequent process of FIG. 2D.

FIG. 3A is a partial cross-sectional view of another embodiment of FIG. 2D.

FIG. 3B is a partial top view of FIG. 3A.

FIG. 4A, FIG. 4B and FIG. 4C are partial cross-sectional views of different embodiments of FIG. 2D.

FIG. 5A, FIG. 5B, FIG. 5C and FIG. 5D are partial top views of embodiments of other aspects of FIG. 3B.

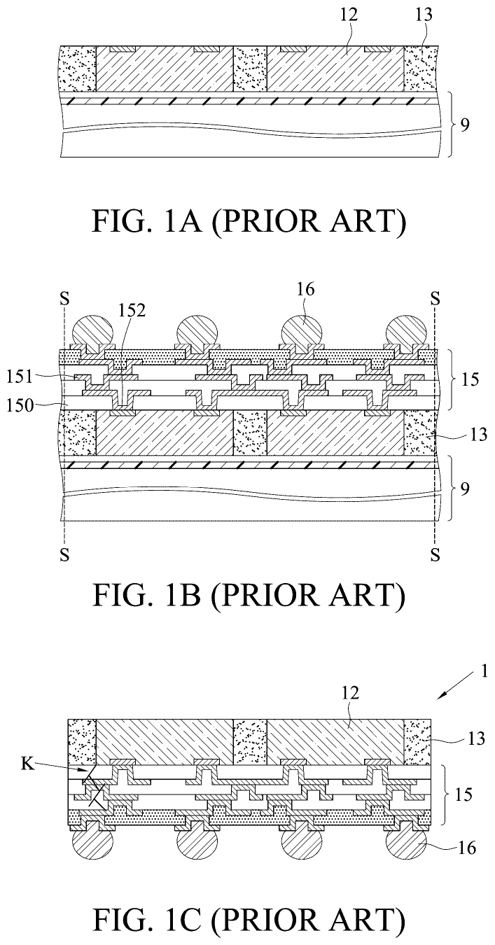

### DETAILED DESCRIPTION

Embodiments of the present disclosure are described below by examples. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes, or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

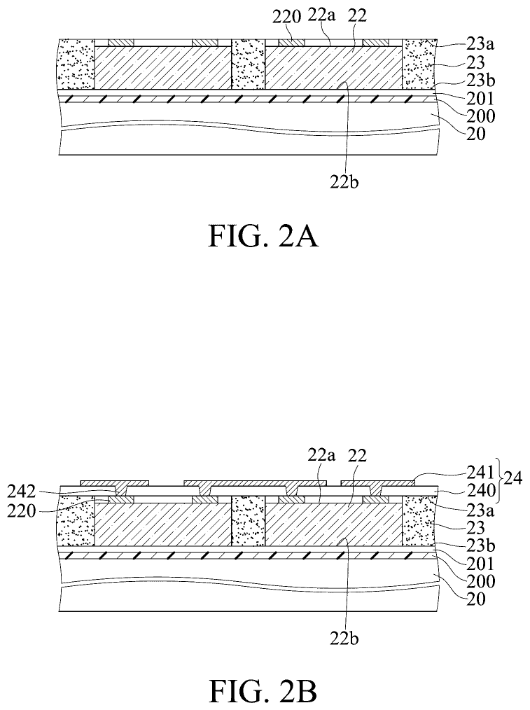

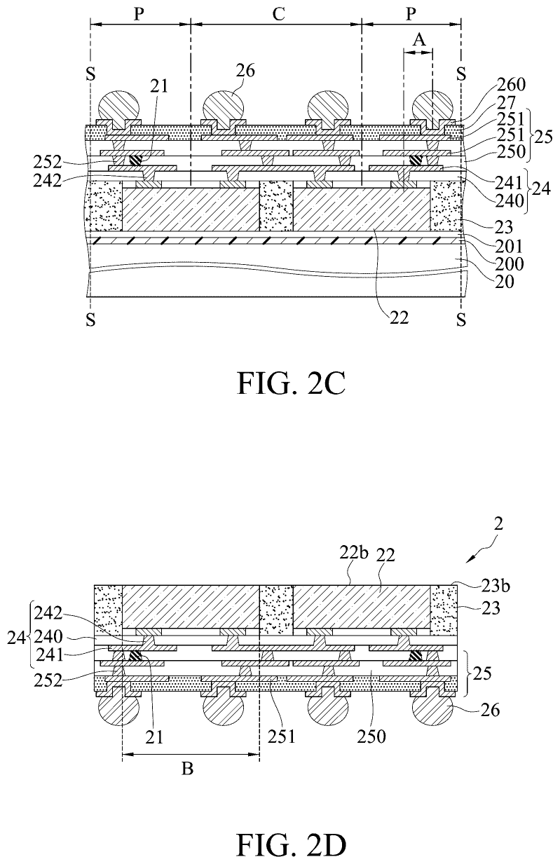

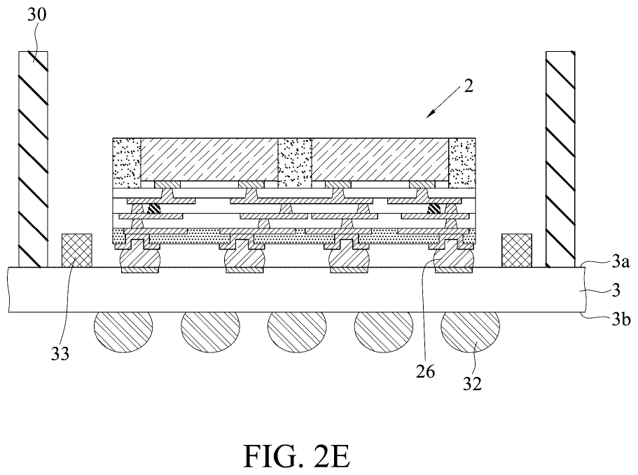

FIG. 2A to FIG. 2D are schematic cross-sectional views illustrating a manufacturing method of an electronic package 2 of the present disclosure.

As shown in FIG. 2A, at least one electronic component 22 (in this embodiment, two electronic components 22 are shown) is disposed on a carrier board 20, and then an encapsulating layer 23 having a first surface 23a and a second surface 23b opposite to the first surface 23a is formed on the carrier board 20 to encapsulate the electronic components 22 so that the electronic components 22 are embedded in the encapsulating layer 23.

The carrier board 20 is formed with a release layer 200 and a bonding layer 201 thereon in sequence, so that the second surface 23b of the encapsulating layer 23 and the electronic components 22 are bonded to the bonding layer 201.

In one embodiment, the release layer 200 is a thermal release tape, a photosensitive release film, or a mechanical release structure, and the bonding layer 201 is made of adhesive material.

The encapsulating layer 23 is made of insulating material, such as dry film, epoxy molding colloid, or epoxy molding compound.

In one embodiment, the encapsulating layer 23 can be formed on the carrier board 20 by liquid compound, injection, lamination, or compression molding.

The electronic component 22 is an active component, a passive component, or a combination of the active component and the passive component, wherein the active component is a semiconductor chip, and the passive component is a resistor, a capacitor, or an inductor.

In one embodiment, the electronic component 22 is a semiconductor chip and has an active surface 22a and an inactive surface 22b opposite to the active surface 22a. The active surface 22a has a plurality of electrode pads to bond to a plurality of conductive bumps 220. The inactive surface 22b of the electronic component 22 is bonded to the bonding layer 201. The plurality of conductive bumps 220 are exposed from the first surface 23a of the encapsulating layer 23.

As shown in FIG. 2B, a wiring structure 24 is formed on the first surface 23a of the encapsulating layer 23. The wiring structure 24 includes an insulating layer 240 formed on the encapsulating layer 23, a wiring layer 241 formed on the insulating layer 240, and a plurality of first conductive blind vias 242 formed in the insulating layer 240, wherein the plurality of first conductive blind vias 242 are electrically connected to the wiring layer 241 and the conductive bumps 220 of the electronic components 22.

In one embodiment, the wiring structure 24 is of a redistribution layer (RDL) specification.

Furthermore, the wiring layer 241 and the first conductive blind vias 242 are made of copper, and the insulating layer 240 is made of dielectric material such as polybenzoxazole (PBO), polyimide (PI), prepreg (PP), or the like.

As shown in FIG. 2C, a circuit structure 25 is formed on the wiring structure 24, and at least one reinforced blind via 21 is formed in the circuit structure 25, wherein the circuit structure 25 includes at least one dielectric layer 250 formed on the insulating layer 240, at least one circuit layer 251 formed on the dielectric layer 250, and a plurality of second conductive blind vias 252 formed in the dielectric layer 250, wherein the second conductive blind vias 252 are electrically connected to the circuit layer 251 and the wiring layer 241.

In one embodiment, the circuit structure 25 is of an RDL specification, the circuit layer 251 and the second conductive blind vias 252 are made of copper, and the circuit structure 25 includes a plurality of the dielectric layers 250. The dielectric layer 250 is made of dielectric material such as polybenzoxazole (PBO), polyimide (PI), prepreg (PP), or the like. In addition, the outermost side of the circuit structure 25 can be formed with an insulating protective layer 27. The insulating protective layer 27 can be made of solder-resist material such as solder mask (green paint), graphite, or others. Parts of the surface of the outermost circuit layer 251 are exposed from the insulating protective layer 27 for bonding a plurality of conductive components 26. For example, the conductive components 26 are solder bumps or metal bumps containing solder material of a controlled-collapse chip connection (C4) specification, and an under bump metallurgy (UBM) layer 260 can be formed on the circuit layer 251 before the conductive components 26 are formed so as to facilitate the bonding of the conductive components 26.

In addition, the dielectric layer 250 may be made of the same material as the insulating layer 240, and the circuit layer 251 and the second conductive blind vias 252 may be made of the same material as the wiring layer 241 and the first conductive blind vias 242.

Furthermore, the first conductive blind vias 242 and the second conductive blind vias 252 are not aligned with each other and are offset from each other, so that a target area A is formed in the dielectric layers 250 between the first conductive blind vias 242 and the second conductive blind vias 252. For example, the circuit structure 25 is defined with a middle area C and a peripheral area P surrounding the middle area C, and the second conductive blind vias 252 are arranged in the peripheral area P and the middle area C, so that the target area A is formed in the dielectric layers 250 of the peripheral area P.

Also, the reinforced blind via 21 is a conductor made of metal material and is formed together with the second conductive blind via 252, so that the reinforced blind via 21 is formed in at least one dielectric layer 250 in the target area A.

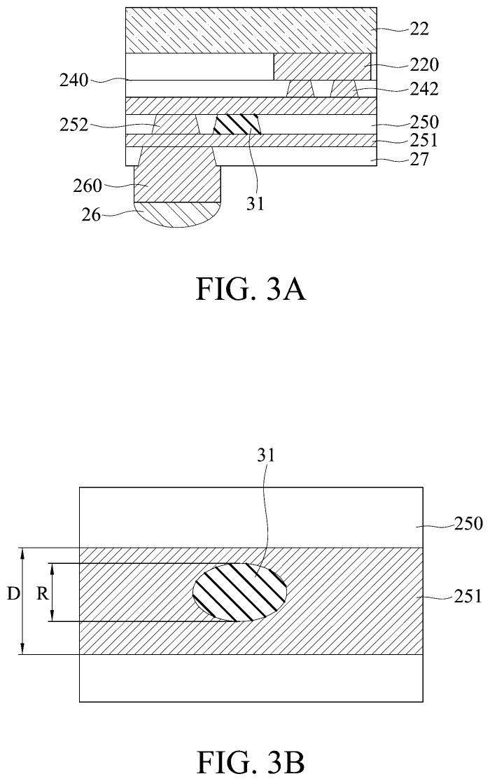

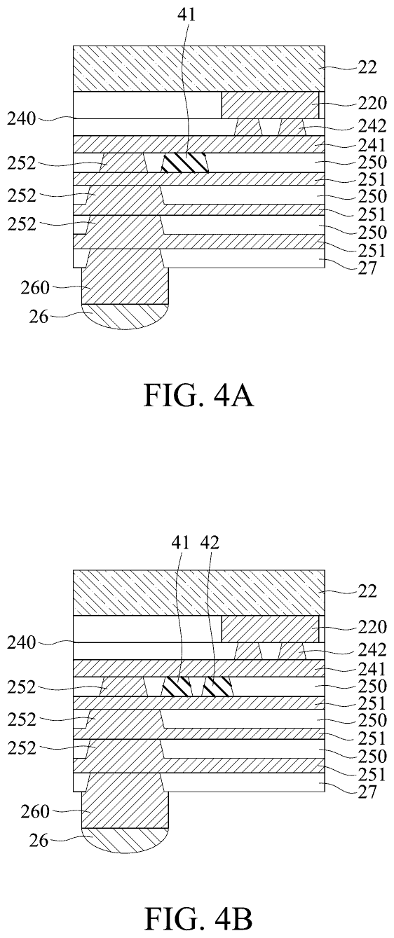

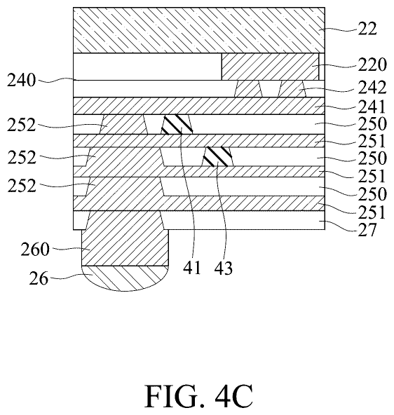

In one embodiment, the number of the dielectric layers 250 can be designed as required, such as two dielectric layers 250 shown in FIG. 2C, or one dielectric layer 250 shown in FIG. 3A, so that the position of the reinforced blind via 21 can be configured as required in any dielectric layer 250 in the target area A. For example, the reinforced blind via 21, 41 shown in FIG. 2C or FIG. 4A is located in the dielectric layer 250 close to the insulating layer 240 (that is, the reinforced blind via 21, 41 is in the dielectric layer 250 adjacent to the insulating layer 240 so as to be as close as possible to the electronic component 22, because the closer to the electronic component 22, the greater the stress on the circuit layer 251), or a reinforced blind via 43 shown in FIG. 4C is located in an intermediate dielectric layer 250.

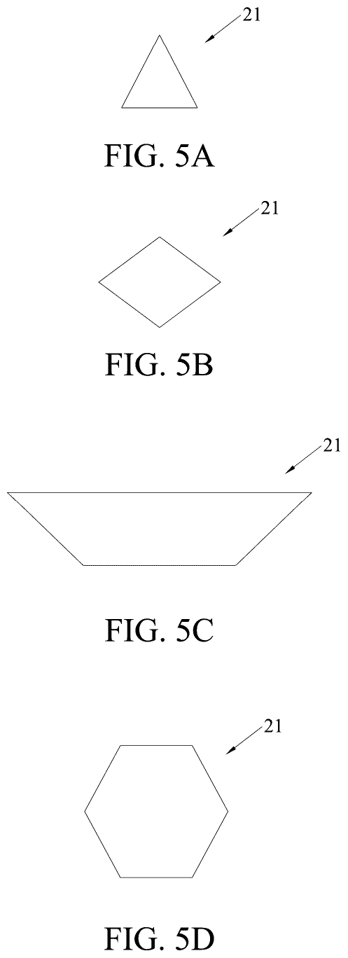

In addition, the reinforced blind via 21 is not aligned with the first conductive blind via 242 and the second conductive blind via 252, so that the reinforced blind via 21, the first conductive blind via 242 and the second conductive blind via 252 are offset from each other. For example, a width R of a reinforced blind via 31 can be less than a width D of the circuit layer 251 (as shown in FIG. 3B) or equal to the width D of the circuit layer 251 (not shown) to facilitate misalignment. Further, a planar shape of the reinforced blind via 21, 31 can be designed according to the misalignment requirements, such as ellipse (as shown in FIG. 3B), circle, polygon (as shown in FIG. 5A to FIG. 5D), or other kinds of geometric figure, but the present disclosure is not limited to as such.

As shown in FIG. 2D, the carrier board 20, the release layer 200 and the bonding layer 201 are removed, so that the inactive surface 22b of each of the electronic components 22 is exposed from the second surface 23b of the encapsulating layer 23. After that, a singulation process is performed along a cutting path S as shown in FIG. 2C.

In one embodiment, the reinforced blind via 21 is located within a vertical projection area B of the electronic component 22, preferably located at the edge of the vertical projection area B of the electronic component 22.

In addition, as shown in FIG. 2E, in subsequent processes, the electronic package 2 can be coupled to an electronic device 3 such as a circuit board via the conductive components 26, wherein the electronic package 2, at least one heat dissipation member 30 and at least one passive component 33 are disposed on an upper side 3a of the electronic device 3, and a plurality of solder balls 32 are disposed on a lower side 3b of the electronic device 3.

Accordingly, in the manufacturing method of the present disclosure, at least one reinforced blind via 21 is formed in the target area A, and the reinforced blind via 21, the first conductive blind via 242 and the second conductive blind via 252 are offset from each other to disperse the stresses in the wiring structure 24 and the circuit structure 25. Therefore, compared with the prior art, the electronic package 2 can effectively prevent the problem of stress concentration from occurring to the wiring structure 24 and the circuit structure 25 so as to prevent the problem of cracking from occurring to the wiring structure 24 or the circuit structure 25, thereby preventing the wiring layer 241 or the circuit layer 251 from being damaged to improve the yield and reliability of the product.

It should be understood that the number of the reinforced blind via 21 in the target area A of the circuit structure 25 can be configured as required, such as one reinforced blind via 41 shown in FIG. 4A, multiple reinforced blind vias 41, 42 formed in the same dielectric layer 250 shown in FIG. 4B, or the reinforced blind vias 41, 43 formed in different dielectric layers 250 shown in FIG. 4C.

The present disclosure further provides an electronic package 2, which includes: an encapsulating layer 23, at least one electronic component 22 embedded in the encapsulating layer 23, a wiring structure 24 formed on the encapsulating layer 23, a circuit structure 25 formed on the wiring structure 24, and at least one reinforced blind via 21, 31, 41, 42, 43 formed in the circuit structure 25.

The wiring structure 24 includes an insulating layer 240 formed on the encapsulating layer 23, a wiring layer 241 formed on the insulating layer 240, and a plurality of first conductive blind vias 242 formed in the insulating layer 240, wherein the plurality of first conductive blind vias 242 are electrically connected to the wiring layer 241 and the electronic components 22.

The circuit structure 25 includes at least one dielectric layer 250 formed on the insulating layer 240, at least one circuit layer 251 formed on the dielectric layer 250, and a plurality of second conductive blind vias 252 formed in the dielectric layer 250, wherein the plurality of second conductive blind vias 252 are electrically connected to the circuit layer 251 and the wiring layer 241, wherein the first conductive blind vias 242 and the second conductive blind vias 252 are offset from each other, and a target area A is formed in the dielectric layer 250 between the first conductive blind vias 242 and the second conductive blind vias 252.

The reinforced blind via 21, 31, 41, 42, 43 is formed in the target area A of the dielectric layer 250.

In one embodiment, the wiring structure 24 and the circuit structure 25 are of redistribution layer (RDL) specifications.

In one embodiment, the circuit structure 25 includes a plurality of the dielectric layers 250. For example, a plurality of the reinforced blind vias 41, 43 are formed in different dielectric layers 250.

In one embodiment, a plurality of the reinforced blind vias 41, 42 are formed in a single dielectric layer 250.

In one embodiment, the reinforced blind via 21, 31, 41, 42, 43 is located in a vertical projection area B of the electronic component 22.

In one embodiment, the reinforced blind vias 41, 42 are located in the dielectric layer 250 adjacent to the insulating layer 240, so as to be as close as possible to the electronic component 22.

In one embodiment, the reinforced blind via 21, 31, 41, 42, 43, the first conductive blind vias 242 and the second conductive blind vias 252 are offset from each other.

In one embodiment, a planar shape of the reinforced blind via 21, 31, 41, 42, 43 is a geometric figure.

In one embodiment, a width R of the reinforced blind via 21 is less than or equal to a width D of the circuit layer 251.

In view of the above, in the electronic package and manufacturing method thereof according to the present disclosure, at least one reinforced blind via is formed in the target area to disperse the stresses in the wiring structure and the circuit structure. Therefore, the electronic package can prevent stress concentration from occurring to the wiring structure and the circuit structure and prevent the problem of cracking from occurring to the wiring structure or the circuit structure.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
an encapsulating layer;
at least one electronic component embedded in the encapsulating layer;
a wiring structure formed on the encapsulating layer and including an insulating layer formed on the encapsulating layer, a wiring layer formed on the insulating layer, and a plurality of first conductive blind vias formed in the insulating layer, wherein the plurality of first conductive blind vias are electrically connected to the wiring layer and the at least one electronic component;
a circuit structure formed on the wiring structure and including at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the first conductive blind vias and the second conductive blind vias are offset from each other, and a target area is formed in the dielectric layer between the first conductive blind vias and the second conductive blind vias; and
a reinforced blind via formed in the target area of the dielectric layer.

2. The electronic package of claim 1, wherein the wiring structure and the circuit structure are of redistribution layer specifications.

3. The electronic package of claim 1, wherein the circuit structure includes a plurality of the dielectric layers.

4. The electronic package of claim 3, wherein a plurality of the reinforced blind vias are arranged in the different dielectric layers.

5. The electronic package of claim 1, wherein a plurality of the reinforced blind vias are arranged in the single dielectric layer.

6. The electronic package of claim 1, wherein the reinforced blind via is located in a vertical projection area of the electronic component.

7. The electronic package of claim 1, wherein the reinforced blind via is located in the dielectric layer adjacent to the insulating layer.

8. The electronic package of claim 1, wherein the reinforced blind via, the first conductive blind vias and the second conductive blind vias are offset from each other.

9. The electronic package of claim 1, wherein a planar shape of the reinforced blind via is a geometric figure.

10. The electronic package of claim 1, wherein a width of the reinforced blind via is less than or equal to a width of the circuit layer.

11. A method of manufacturing an electronic package, comprising:
forming an encapsulating layer on at least one electronic component to encapsulate the at least one electronic component;
forming a wiring structure on the encapsulating layer, wherein the wiring structure includes an insulating layer formed on the encapsulating layer, a wiring layer formed on the insulating layer, and a plurality of first conductive blind vias formed in the insulating layer, wherein the plurality of first conductive blind vias are electrically connected to the wiring layer and the at least one electronic component;
forming a circuit structure on the wiring structure, wherein the circuit structure includes at least one dielectric layer formed on the insulating layer, at least one circuit layer formed on the dielectric layer, and a plurality of second conductive blind vias formed in the dielectric layer, wherein the plurality of second conductive blind vias are electrically connected to the circuit layer and the wiring layer, wherein the first conductive blind vias and the second conductive blind vias are offset from each other, and a target area is formed in the dielectric layer between the first conductive blind vias and the second conductive blind vias; and
forming a reinforced blind via in the target area of the dielectric layer.

12. The method of claim 11, wherein the wiring structure and the circuit structure are of redistribution layer specifications.

13. The method of claim 11, wherein the circuit structure includes a plurality of the dielectric layers.

14. The method of claim 13, wherein a plurality of the reinforced blind vias are arranged in the different dielectric layers.

15. The method of claim 11, wherein a plurality of the reinforced blind vias are arranged in the single dielectric layer.

16. The method of claim 11, wherein the reinforced blind via is located in a vertical projection area of the electronic component.

17. The method of claim 11, wherein the reinforced blind via is located in the dielectric layer adjacent to the insulating layer.

18. The method of claim 11, wherein the reinforced blind via, the first conductive blind vias and the second conductive blind vias are offset from each other.

19. The method of claim 11, wherein a planar shape of the reinforced blind via is a geometric figure.

20. The method of claim 11, wherein a width of the reinforced blind via is less than or equal to a width of the circuit layer.
